(19) United States
(12) Patent Application Publication
(10) Pub. No.: US 2006/0259840 A1
(43) Pub. Date: Nov. 16, 2006

(54) SELF-TEST CIRCUITRY TO DETERMINE MINIMUM OPERATING VOLTAGE

(75) Inventors: Wagdi W. Abadeer, Jericho, VT (US); George M. Braceras, Essex Junction, VT (US); Anthony R. Bonaccio, Shelburne, VT (US); Kevin W. Gorman, Fairfax, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 10/908,452

(22) Filed: May 12, 2005

(51) Int. Cl. G01R 31/28

(52) U.S. Cl. 714/733

(57) ABSTRACT

A solution for determining minimum operating voltages due to performance/power requirements would be valid for a wide range of actual uses. The solution includes a test flow methodology for dynamically reducing power consumption under applied conditions while maintaining application performance via a BIST circuit. There is additionally provided a test flow method for dynamically reducing power consumption to the lowest possible stand-by/very low power level under applied conditions that will still be sufficient to maintain data/state information. One possible application would be for controlling the voltage supply to a group of particular circuits on an ASIC (Application Specific Integrated Circuit). These circuits are grouped together in a voltage island where they would receive a voltage supply that can be different from the voltage supply other circuits on the same chip are receiving. The same solution could be applied to a portion of a microprocessor (the cache logic control, for example).

### BACKGROUND OF THE INVENTION

1. Field of the Invention

The present invention relates generally to integrated circuits, and, more particularly, to a system and method for determining a minimum operating voltage of the IC and dynamically changing the minimum operating voltage of the IC.

2. Description of the Prior Art

Power consumption is becoming increasingly important, both to minimize the power consumed and the heat dissipated by a device. A key component of power consumption in deep sub-micron technologies is the power attributed to leakage current. Leakage can be reduced substantially by reducing the voltage used by the circuit, which in turn substantially reduces the power consumption of the circuit.

Previous designs have supported voltage supply adjustments to maintain performance, but most designs simply reduce clock cycle frequency to reduce power. Additionally, the various voltage/clock frequency set points are not determined on a chip-by-chip basis.

U.S. Pat. No. 6,345,362 to Bertin, et al. (IBM), teaches an integrated circuit with intelligent power management, whereby the power management unit controls the threshold voltage of the different functional units to optimize power performance operation of the circuit. A status table, coupled to both a decode unit and a logic unit, compares the functional units required for a particular instruction to the power status to determine if the functional units are at optimal power level. If they are, the command proceeds, if not, either a stall is executed or the process speed is modified.

Related patent, U.S. Pat. No. 6,477,654 to Dean, et al., teaches a method of operating a programmable integrated circuit to reduce power, whereby power control instructions are embedded in the instruction commands as defined by the user which are used by a power management system to optimize the power consumption of various functional units.

U.S. Pat. No. 5,086,501 teaches one method for determining and selecting the minimum operating voltage of a computing system.

U.S. Pat. No. 6,757,857 discloses use of an AC Built-In Self-Test (BIST) with a variable data receiver voltage reference.

U.S. Patent Application Publication No. 2003/0223276 described a semiconductor SRAM memory circuit that may be operated at a lower operating voltage.

The reference entitled “Pushing ASIC Performance in Power Envelope”, authored by Ruchir Puri, et al. describes use of voltage islands for ASIC designs and particularly, a method that enable multiple supply voltages in ASIC designs that result in substantial device power savings.

It would be highly desirable to provide a self-test system and methodology for determining the minimum operating voltage of an IC having a voltage island under test that includes both logic and memory arrays.

### SUMMARY OF THE INVENTION

It is an object of the present invention to provide a system and method for reducing supply voltage in order to reduce power consumption in semiconductor circuits, while still maintaining at-application speed performance. Additional lower power modes can also be created to further reduce power consumption at less than normal application speed performance settings.

According to the invention, a Built-In-Self-Test (BIST) circuit is used to determine the correct supply voltage for all elements in a design (which takes into account variability between devices on a chip). This produces a much more accurate supply voltage setting necessary to achieve either certain performance set-points or to maintain data integrity during standby.

According to the invention, the BIST circuitry can be run to determine the supply voltage settings on a chip-by-chip basis. Chips that can achieve higher performance at lower voltages also tend to produce more leakage. The leakage can be reduced while still maintaining the desired performance by operating the chips″circuits at a lowered voltage. Chips capable of reduced performance, which would need an elevated voltage to perform at the desired speed, tend to produce less leakage. The performance of these chips can be improved while still maintaining low leakage by operating the chips' circuits at an elevated voltage. Tailoring the supply voltage settings individually allows for many more chips to both meet the power and performance targets that are required. Since the BIST tests virtually all devices in the circuits in the Voltage Islands (VI)'s in question the voltage supply is essentially tailored to meet the requirements of the worst performing device within a VI on a chip-by-chip basis.

The BIST can also be run in-system-either dynamically as conditions change, or on power up. This allows the supply voltage to be tailored to the immediate environment and to take into account end of life (NBTI) effects that result in reduced performance.

According to one aspect of the invention, there is provided a system and method for dynamically changing the minimum operating voltage of a semiconductor chip, the method comprising the steps of:

providing Built-In-Self-Test (BIST) test means for testing a voltage island under test (VIUT) having circuitry operating in accordance with a particular application, wherein the BIST test means is operatively coupled to the voltage island under test for testing the circuitry to determine the lowest operating voltage required by the voltage island to provide for a passing BIST test;

generating a control signal representing the lowest operating voltage; and,

adjusting a power supply voltage applied to the VIUT based on the generated control signal so as to provide the minimum operating voltage for the circuitry.

According to a further aspect of the invention, there is provided a system and method for determining the performance characteristics of an Integrated-Circuit (IC) having circuitry operating in accordance with a particular application, the method comprising:

detecting an operating mode of the IC;

testing the IC using a BIST test circuit in response to a detected operating mode, the test circuit being operatively coupled to the IC circuitry for testing said circuitry to determine the lowest operating voltage value required by the IC circuitry to provide for a passing BIST test;

generating a control signal representing the lowest operating voltage value for that operating mode; and,

storing the control signal in a memory device associated with the IC.

Advantageously, the solution for determining minimum operating voltages due to performance/power requirements would be valid for a wide range of actual uses. One possible application would be for controlling the voltage supply to a group of particular circuits on an ASIC (Application Specific Integrated Circuit). These circuits are grouped together in the voltage island where they would receive a voltage supply that can be different from the voltage supply other circuits on the same chip are receiving. The same solution could be applied to memory arrays, or a portion of a microprocessor (cache logic circuitry, for example).

### BRIEF DESCRIPTION OF DRAWINGS

The objects, features and advantages of the present invention will become apparent to one skilled in the art, in view of the following detailed description taken in combination with the attached drawings, in which:

FIG. 1 is a block diagram of the system 10 according to the present invention;

FIG. 2 graphically describes a test flow method 100 for dynamically reducing power consumption under applied conditions while maintaining application performance via BIST;

FIG. 3 depicts a test flow method for dynamically reducing power consumption to the lowest possible stand-by/very low power level under applied conditions that will still maintain data/state information;

FIG. 4 depicts a test flow method for determining both minimum power consumption while maintaining application performance and minimum power consumption for stand-by/very low power (while maintaining data/state information) via BIST during manufacturing test; and,

FIG. 5 depicts a test flow method for determining both minimum power consumption while maintaining application performance and minimum power consumption for stand-by/very low power (while maintaining data/state information) via BIST at power up.

### DETAILED DESCRIPTION OF THE PREFERRED EMBODIMENTS

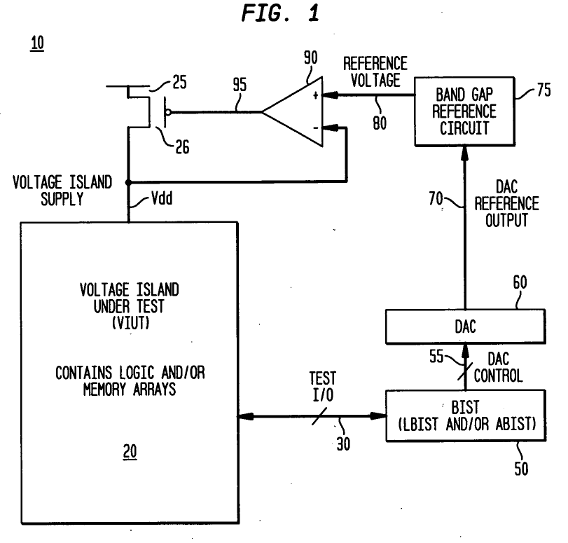

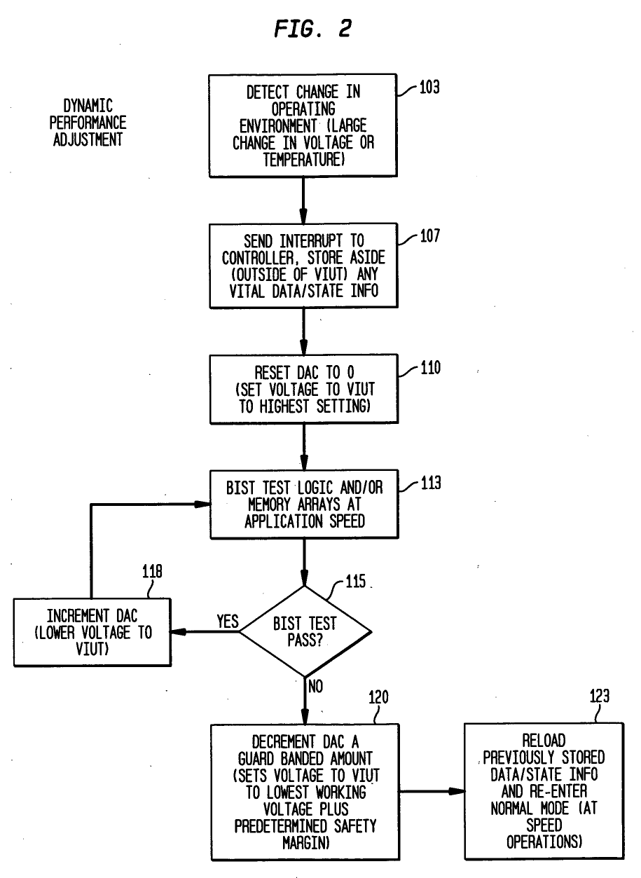

FIG. 1 is a block diagram of the system 10 according to the invention. As shown in FIG. 1, the system 10 comprises a voltage island under test (“VIUT”) block 20 having a voltage supply source 25 depicted as a Vdd through a gated transistor 26. Test input/output signal lines 30 connect the operative elements of the voltage island circuits to a Built-In-Self-Test (BIST) circuit 50 adapted for (Logic BIST) LBIST and/or (Array BIST) ABIST modes of operation. As will be described in detail with respect to FIG. 2, the BIST executes a performance test of the logic and/or memory arrays at application speed and outputs digital control signals 55 that are input to a Digital-to-Analog Converter (DAC) device 60. The DAC 60 outputs an analog reference signal 70 that is input to a bandgap reference circuit 75 that generates a reference voltage 80. The reference voltage 80 is input to a voltage supply regulator comprising an operational amplifier device 90 and transistor device 26. The op-amp device 90 compares the reference voltage 80 with the current operating power supply voltage Vdd and generates a feedback control signal 95 that regulates and adjusts the Vdd supply voltage accordingly through transistor device 26, e.g., a PFET.

It should be understood that while a single BIST device 50 is shown in FIG. 1, it may be used to control multiple VIUT provided the circuits in the voltage islands are of a similar nature (an SRAM BIST typically has a different structure and produces a different set of test stimuli compared to a DRAM BIST or a Logic BIST). A voltage island that contains a mix of logic and memory devices may require multiple BIST types working together to stimulate the contents of the voltage island and determine the pass/fail status of all circuits in the island. The first BIST to report a fail would then stop the testing and force the guard band to be added to the DAC value.

It is further understood that the bandgap reference circuit 75 produces a constant output voltage 80 that ideally does not vary with process, temperature or voltage. This is achieved by supplying a single input current to two differently sized diodes (diodes with different current densities), for example, that will develop different voltages across themselves which are necessary to sustain the different current densities. The difference between the voltages across the two diodes generates an internal reference voltage. A variety of circuits can then be used to remove the temperature dependence of the resulting internal reference voltage. The input to this bandgap reference circuit 75 is a current 70 and the output is a final reference voltage 80 that does not vary with process/voltage/temperature.

Thus, in accordance with the system of the invention depicted in FIG. 1, the DAC 60 converts the digital control word that is controlled by a counter in the BIST (or a counter shared among multiple BIST's) into an analog signal (typically a current of a particular magnitude). The analog signal is used to adjust the reference voltage that the bandgap reference circuit 75 produces. As the reference circuit output changes the op-amp/pFET device (acting together as a voltage regulator) adjust the voltage supply to the voltage island 20.

Alternatively, the bandgap reference circuit 75 may produce a static voltage output signal from a static input current and the digital output of the BIST simply trims the reference circuit output voltage producing a new reference voltage that drives the op-amp/regulator. This configuration is not shown, but well within the purview of skilled artisans.

FIG. 2 graphically describes a test flow method 100 for dynamically reducing power consumption under applied conditions while maintaining application performance via BIST. As shown in FIG. 2, there is depicted a first step 103 representing the step of detecting a change in operating environment (a large change in voltage or temperature, for example). As known, there may be employed any number of circuits for determining temperature and/or voltage changes. Many of today's microprocessors use these types of circuits for dynamically adjusting voltage within a pre-determined range. The voltage range is usually fixed because the microprocessor can not determine the actual failing voltage level on a chip by chip basis in an automatic fashion. The present invention thus provides a system implementing a methodology that can determine the actual failing voltage level on a chip, if necessary, but moreover determines the necessary voltage to minimize power, maximize circuit performance, or just maintain stored data at any point during normal operation of the chip. The reason why BIST is triggered by changes in the chip's environment is that these changes could cause the current minimum operating voltage to become invalid. The BIST needs to be run in order to dynamically adjust the minimum operating voltage necessary to fulfill one of these criteria in order to react to these changes in the environment, otherwise the power may not be minimized, the performance may not be maximized, or the stored data may not be maintained once the surrounding environment changes. It is understood however, that any other trigger could also be used to dynamically cause the minimum operating voltage to be re-determined. A timer could trigger the same method after a certain amount of time or, after a particular number of clock cycles have passed, an external interrupt from off the chip could be used, for example.

Upon detection of such a change in the operating environment, as depicted at step 107, the system generates an interrupt to the controller and initiates storage of any vital data/state information. Preferably, this information is stored external to the VIUT block. Then, as indicated at step 110, the DAC device 60 is reset to a “0” or initial setting corresponding to a voltage (Vdd) input to the voltage supply island (VIUT 20) at its highest setting. Then, as shown at step 113, a further step is to initiate BIST test of the logic and/or memory arrays at the speed of a particular application, and, at step 115, a determination is made as to whether the BIST test passes. If it is determined that the BIST test passes at step 115, then the process proceeds to step 118 to increment the DAC which effectively causes a reduction in the voltage applied to the VIUT block. The process then proceeds back to step 113 to again apply BIST test logic and/or memory arrays at the speed of a particular application. These series of steps 113, 115 and 118 are repeated until the BIST test fails, at which point the process proceeds to step 120 to decrement the DAC a guard banded amount—which is a decrement that enables setting of the supply voltage to the VIUT to a lowest working voltage plus a predetermined safety margin. Subsequently, the previously stored data/state information is reloaded and the system is re-entered into normal mode (at speed operations) as indicated at step 123, FIG. 2.

It should be understood that, as referred to herein, application “speeds” vary for the particular instance when applying the solution of the invention. For example, according to the invention, for a microprocessor cache the voltage may be adjusted to permit operation in the multi-GHz frequency range. For a high performance ASIC the voltage may typically be adjusted to permit operation from 300 MHz to around 1 GHz (this would vary widely depending on the application the ASIC was targeted towards). For an ASIC targeted at a low power application (cellular phones for example) the voltage might be lowered to minimize power consumption.

Furthermore, it is understood that a typical DAC (Digital to Analog Converter) may receive input from the BIST, for example, from an output of a binary counter that would be controlled by the BIST Self Test logic. For an application that is seeking to minimize the operating voltage while still maintaining some target performance of “x”MHz (with a nominal voltage of 1.2V, for example) a 6 bit counter could be used to drive the DAC (as it would provide an input range of 64 steps). Thus, an increment/decrement of one (1) step may result in the DAC generating a change in the voltage relative to the nominal value of around 0.5% (e.g., 6 mV) to allow for adjusting the operating voltage over 384 mV. The operating range, as controlled by the DAC, would then perhaps be 1.296V to 0.912V (for a total ideal range of 384 mV that still encompasses the nominal voltage of 1.2V).

Moreover, it should be understood that the guard banded amount would vary with each application. The BIST Self Test logic may be adjusting the voltage to SRAM, DRAM, or normal logic. An SRAM may have a different voltage guard band requirement compared to a DRAM compared to a standard logic latch. The application's expected voltage supply noise would also be critical in determining the correct guard band. If the application is expecting to see voltage supply noise events on the order of 50 mV (where a noise event would cause the voltage supply to “droop” 50 mV below its ideal level) then the guard band should take this into account. For the DAC example above, a guard band on the order of 5% of the nominal operating voltage might be appropriate. The 6-bit binary value representing a failing voltage would be found. A guard band of 5% would be taken (the counter would be adjusted by 10 steps to increase the voltage), providing a guard band of 60 mV over the failing voltage.

Thus, the actual DAC specification should more than likely vary for each application. The values represented above are just probable idealized design points for a typical 1.2V ASIC application with the understanding that a true DAC is never perfectly linear (every step would not be exactly 6 mV for example).

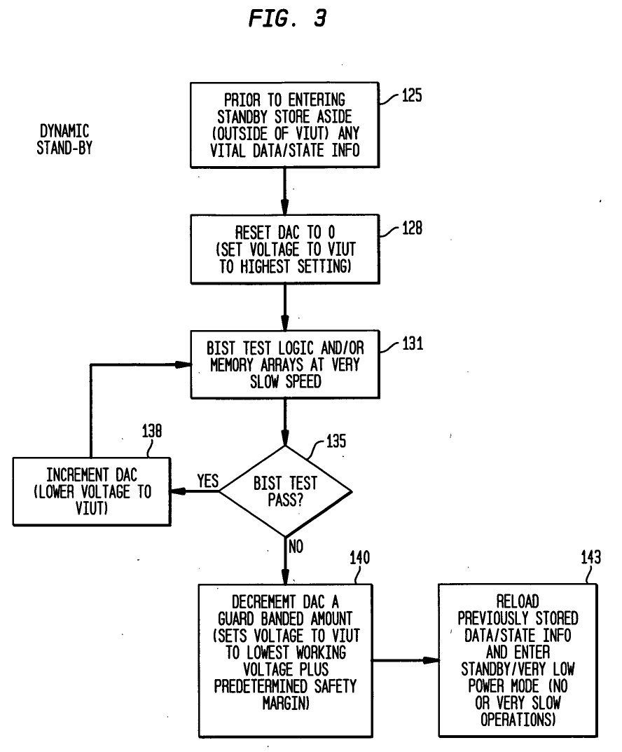

FIG. 3 graphically describes a test flow method for dynamically reducing power consumption to the lowest possible stand-by/very low power level under applied conditions that will still maintain data/state information. As shown in FIG. 3, there is depicted a first step 125 representing the step of storing by storage means external to the VIUT block, any vital data/state information maintained by the system prior to entering into the standby condition. Afterward, at step 128, the DAC block 60 is reset to “0” for example, or the predetermined setting that will effectively set the voltage to the VIUT to its highest setting. Then, step 131 is performed which is the actual BIST test logic step and/or BIST memory arrays test at a very slow speed. Then, at step 135, a determination is made as to whether the BIST test passes at the slow speed. If it is determined that the BIST test passes at step 135, then the process proceeds to step 138 to increment the DAC which effectively causes a reduction in the voltage applied to the VIUT block. The process then proceeds back to step 131 to again apply BIST test logic and/or memory arrays at the very slow speed. These series of steps 131, 135 and 138 are repeated until the BIST test fails, at which point the process proceeds to step 140 to decrement the DAC a guard banded amount—which is a decrement that enables setting of the supply voltage to the VIUT to a lowest working voltage plus a predetermined safety margin. Subsequently, the previously stored data/state information is reloaded and the system is re-entered into standby/very low power mode (where no or very slow speed operations are performed) as indicated at step 143, FIG. 3. This voltage level, if used for a standby mode, would be the lowest voltage supply that still allows the memory and/or latches in a voltage island to maintain data. This voltage level, if used for a very low power mode, would be the lowest voltage supply that still allows circuits to functionally operate at very slow speeds.

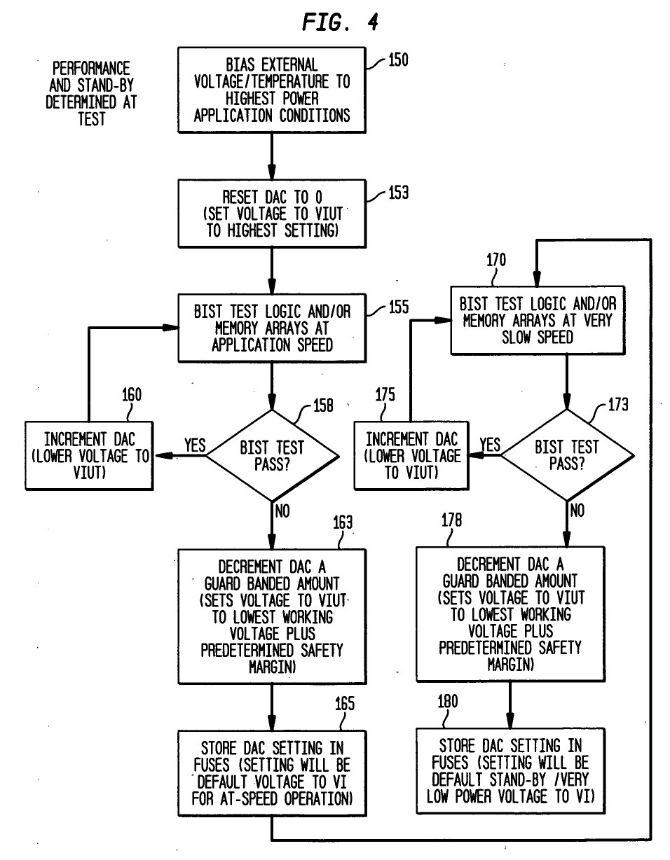

FIG. 4 graphically describes a test flow method for determining both minimum power consumption while maintaining application performance and minimum power consumption for stand-by/very low power (while maintaining data/state information) via BIST during manufacturing test. The values determined at test and stored in a non-volatile memory (such as fuses) will then be used to immediately switch the voltage island (VI) voltage supply between the at-application speed operational setting and the stand-by/very low power operational setting, reducing the need to run BIST in-system. As shown at first step 150, FIG. 4, there is depicted the step of applying an external bias to the application conditions, i.e., bias external voltage/temperature to highest power application conditions. Then, at step 153, the DAC block 60 is reset to “0” for example, or the predetermined setting that will effectively set the voltage to the VIUT to its highest setting. Then, as indicated at step 155, the BIST test logic and/or test memory arrays is performed at application speeds. Then, at step 158, a determination is made as to whether the BIST test passes at the application speed. If it is determined that the BIST test passes at step 158, then the process proceeds to step 160 to increment the DAC which effectively causes a reduction in the voltage applied to the VIUT block. The process then proceeds back to step 155 to again apply BIST test logic and/or memory arrays at the application speed. These series of steps 155, 158 and 160 are repeated until the BIST test fails, at which point the process proceeds to step 163 to decrement the DAC a guard banded amount—which is a decrement that enables setting of the supply voltage to the VIUT to a lowest working voltage plus a predetermined safety margin. Subsequently, at step 165, the DAC setting is stored as a control word in fuse devices to function as a default setting whereby, subsequently, a corresponding default voltage may be applied to the VI for at-speed operation, based on the stored fuse device settings. Continuing to step 170 in FIG. 4, this step represents the step of performing the BIST test logic and/or memory arrays test at very slow speeds. Then, at step 173, a determination is made as to whether the BIST test passes at the slow speed. If it is determined that the BIST test passes at step 173, then the process proceeds to step 175 to increment the DAC which effectively causes a reduction in the voltage applied to the VIUT block. The process then proceeds back to step 170 to again apply BIST test logic and/or memory arrays at the very slow speed. These series of steps 170, 173 and 175 are repeated until the BIST test fails, at which point the process proceeds to step 178 to decrement the DAC a guard banded amount—which is a decrement that enables setting of the supply voltage to the VIUT to a lowest working voltage plus a predetermined safety margin. Subsequently, at step 180, the DAC setting is stored as a control word in fuse devices to subsequently function as providing a default stand-by/very low power voltage setting to the VI.

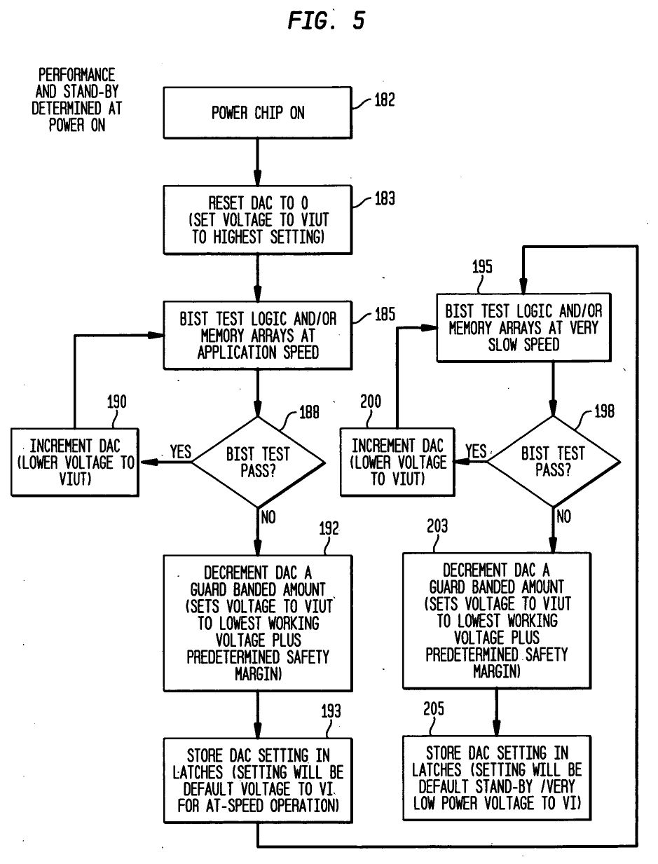

FIG. 5 describes a test flow method for determining both minimum power consumption while maintaining application performance and minimum power consumption for stand-by/very low power (while maintaining data/state information) via BIST at power up. The latched values will then be used to immediately switch VI voltage supply between the at-application speed operational setting and the stand-by/very low power operational setting, reducing ssthe need to run BIST dynamically. As shown at first step 182, FIG. 5, there is depicted the step of applying power to the integrated circuit chip employed with the BIST self-test circuitry according to the invention. Then, at step 183, the DAC block 60 is reset to “0” for example, or the predetermined setting that will effectively set the voltage to the VIUT to its highest setting. Then, as indicated at step 185, the BIST test logic and/or test memory arrays is performed at application speeds. Then, at step 188, a determination is made as to whether the BIST test passes at the application speed. If it is determined that the BIST test passes at step 188, then the process proceeds to step 190 to increment the DAC which effectively causes a reduction in the voltage applied to the VIUT block. The process then proceeds back to step 185 to again apply BIST test logic and/or memory arrays at the application speed. These series of steps 185, 188 and 190 are repeated until the BIST test fails, at which point the process proceeds to step 192 to decrement the DAC a guard banded amount−which is a decrement that enables setting of the supply voltage to the VIUT to a lowest working voltage plus a predetermined safety margin. Subsequently, at step 193, the DAC setting is stored as a control word in one or more latch devices to function as a default setting whereby, subsequently, a corresponding default voltage may be applied to the VI for at-speed operation, based on the stored latch settings.

Continuing to step 195 in FIG. 5, this step represents the step of performing the BIST test logic and/or memory arrays test at very slow speeds. Then, at step 198, a determination is made as to whether the BIST test passes at the slow speed. If it is determined that the BIST test passes at step 198, then the process proceeds to step 200 to increment the DAC which effectively causes a reduction in the voltage applied to the VIUT block. The process then proceeds back to step 195 to again apply BIST test logic and/or memory arrays at the very slow speed. These series of steps 195, 198 and 200 are repeated until the BIST test fails, at which point the process proceeds to step 203 to decrement the DAC a guard banded amount—which is a decrement that enables setting of the supply voltage to the VIUT to a lowest working voltage plus a predetermined safety margin. Subsequently, at step 205, the DAC setting is stored as a control word in latch devices to subsequently function as providing a default stand-by/very low power voltage setting for the VI based on the information stored in the latches.

It should be understood that, according to the invention, fuses or any other non-volatile memory (Flash memory for example) can be used for saving DAC settings when the chip is powered off, while latches or any other volatile memory (SRAM/DRAM for example) can be used for saving settings while the chip is powered on. A typical design may use a combination of these methods. The volatile/non-volatile methods for storing the DAC settings necessary for correct operation under certain circumstances can be located inside the BIST engine, external to the BIST engine, or external to the chip.

It should be noted that the various embodiments of the invention depicted in the methodology described in FIGS. 2-5 represent methods for reducing power by determining the lowest voltage supply necessary to maintain maximum performance or the lowest voltage supply necessary to maintain data. In reality there are any number of other settings possible that could be calculated dynamically, at manufacturing test, or at power up. These settings could include a high performance mode with an elevated voltage that provides above-normal application speed performance, or various mid-range voltages that could produce somewhat reduced application speed performance with a much reduced power consumption. Thus, the system and method of the invention may derive one or both or a multiplicity of control words for a variety of voltage/performance levels and it is intended that the storage device implemented, e.g., memory, fuse or latches, stores all of them.

A device using a chip with a BIST controlled voltage island could thus have a high performance mode (ample power supply available—notebook computer plugged in for example), a normal performance mode, a reduced performance mode (reduced power supply available—notebook computer battery needs to be recharged soon), and a stand-by mode (minimum power supply available—notebook computer battery almost completely drained).

This same BIST controlled voltage regulation technique can be of especially great benefit to embedded memories. The BIST can be used to tune the voltage to maximum yield, minimize power, and still maintain performance. The same methods described may then be used to determine the lowest operating voltage that produces yieldable memories (some weak memory cells will perform in a more robust manner under a higher voltage) that runs at-application speed. For memories that have fewer weak cells or faster performance due to process improvements the voltage can be reduced, which in turn reduces the power.

This same technique presented with respect to FIGS. 2-5 can be used to even more benefit when the memory comprises blocks of cells that each receive a separately regulated voltage supply. The BIST can then tune the voltage supply to each individual block's voltage island to obtain the best yield/power/performance tradeoff. As embedded memories become larger to the point where a single memory can encompass enough chip area to actually include most chip-wide device variations, segmenting the memory into smaller pieces that would be subjected to smaller, localized, device variations, placing each segment into a voltage island, and tuning that island's supply via BIST becomes more attractive.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

What is claimed is:

1. A system for dynamically changing the minimum operating voltage of a semiconductor chip comprising:
a voltage island under test (VIUT) having circuitry operating in accordance with a particular application;
a regulated voltage supply, supplying a source voltage to the circuitry of said voltage island;
a control means for setting a source voltage level to the voltage island; and
a Built-In-Self-Test (BIST) operatively coupled to said voltage island under test for testing said circuitry to determine the lowest operating voltage required by the voltage island to provide for a passing BIST test, and generating a control signal representing said lowest operating voltage, wherein said control means is responsive to said control signal for setting said voltage level to the voltage island to said lowest operating voltage.

2. The system as claimed in claim 1, wherein said circuitry tested at said voltage island comprises logic circuits.

3. The system as claimed in claim 1, wherein said circuitry tested at said voltage island comprises memory array circuits.

4. The system as claimed in claim 1, wherein said BIST testing comprises an iterative process for testing the VIUT circuitry at a predetermined speed, determining whether said BIST test passes and issuing a control signal to said control means for reducing said source voltage applied to the circuitry of said voltage island in response, said iterative process repeating until a BIST Test failure occurs.

5. The system as claimed in claim 4, wherein said control means comprises a Digital-to-Analog converter for setting a source voltage level to the voltage island, said DAC converter responsive to said BIST control signal for adjusting said source voltage applied to said voltage island.

6. The system as claimed in claim 5, wherein said control means comprises means enabling the setting of said source voltage level to a lowest working voltage plus a predetermined voltage amount comprising a safety margin voltage.

7. The system as claimed in claim 4, wherein said circuitry under test comprises an application-Specific-lntegrated-Circuit (ASIC), said BIST testing for testing the VIUT circuitry at a predetermined speed comprises testing said circuitry at an application speed.

8. The system as claimed in claim 4, wherein said circuitry under test comprises a standby mode of operation, said BIST testing for testing the VIUT circuitry at a predetermined speed comprises testing said circuitry at a slow speed such that a minimum lowest possible power level is applied while still providing ability to maintain data information.

9. The system as claimed in claim 4, further comprising means for triggering said test BIST for testing said VIUT circuitry upon detection of an operating condition change.

10. The system as claimed in claim 9, wherein said operating condition change comprises a large change in voltage or temperature.

11. The system as claimed in claim 1, further comprising memory storage means for storing said control signal used for setting an operating state of said VIUT circuitry, said memory storage means comprising one or more of: programmable fuse devices, or latch devices.

12. A method for dynamically changing the minimum operating voltage of a semiconductor chip comprising:
testing a voltage island (VI) having circuitry operating in accordance with a particular application using a Built-In-Self-Test (BIST) test device, wherein said BIST test means is operatively coupled to said voltage island under test for testing said circuitry to determine the lowest operating voltage required by the voltage island to provide for a passing BIST test;
generating a control signal representing said lowest operating voltage; and,
adjusting a power supply voltage applied to the VI based on the generated control signal so as to provide the minimum operating voltage for said circuitry.

13. The method as claimed in claim 12, wherein said BIST test means implements an iterative process comprising steps of:
a) testing the VI circuitry at a predetermined speed;
b) determining whether said BIST test passes and issuing a control signal to a control means adapted for reducing said source voltage applied to the circuitry of said voltage island in response; and,
c) repeating said steps a)-b) until a BIST Test failure occurs.

14. The method as claimed in claim 13, wherein said control means comprises means for setting a source voltage level to the voltage island, said determining step b) comprising responding to said issued BIST control signal for adjusting said source voltage applied to said voltage island at each iteration.

15. The method as claimed in claim 14, wherein control means includes a Digital-to-Analog converter (DAC) means for enables the adjusting of said source voltage level at each iteration.

16. The method as claimed in claim 14, wherein said source voltage level is adjusted to a lowest working voltage plus a predetermined voltage amount comprising a safety margin voltage.

17. The method as claimed in claim 14, wherein said VI circuitry under test comprises an Application-Specific-lntegrated-Circuit (ASIC), said BIST for testing the VI circuitry at a predetermined speed comprises testing said ASIC circuitry at an application speed whereby said source voltage level is adjusted to a lowest working voltage capable of maintaining performance and data integrity for a running application.

18. The method as claimed in claim 14, wherein said VI circuitry under test comprises a standby mode of operation, said BIST testing for testing the VI circuitry at a predetermined speed comprises testing said circuitry at a slow speed such that a minimum lowest possible power level is applied while still providing ability to maintain data information.

19. The method as claimed in claim 14, wherein said BIST testing of said VI circuitry is initiated upon detection of an operating condition change.

20. The method as claimed in claim 19, wherein said operating condition change comprises a change in operating voltage or temperature.

21. The method as claimed in claim 19, wherein prior to said step of triggering said BIST, a step of: storing any vital data or state information used by said application; and, resetting said voltage source such that a highest voltage setting is applied to said VI circuitry.

22. A method for determining the performance characteristics of an Integrated-Circuit (IC) having circuitry operating in accordance with a particular application, said method comprising:
detecting an operating mode of said IC;
testing said IC using a BIST test circuit in response to a detected operating mode, said test circuit being operatively coupled to said IC circuitry for testing said circuitry to determine the lowest operating voltage value required by the IC circuitry to provide for a passing BIST test;
generating a control signal representing said lowest operating voltage value for that operating mode; and,
storing said control signal in a memory device associated with said IC.

23. The method as claimed in claim 22, further comprising the step of:
adjusting a power supply voltage applied to the IC circuitry based on the stored control signal so as to provide a minimum operating voltage for said IC circuitry according to said operating mode.

24. The method as claimed in claim 23, wherein said minimum operating voltage value comprises a lowest working voltage value in addition to a predetermined voltage amount comprising a safety margin voltage.

25. The method as claimed in claim 22, wherein said operating mode of said IC comprises an application speed operational setting, said BIST test circuit testing said IC at a speed corresponding to said application speed operation.

26. The method as claimed in claim 22, wherein said operating mode of said IC comprises a standby mode of operation, said BIST test circuit testing said IC at a speed corresponding to very slow speed operation.

27. The method as claimed in claim 22, wherein said step of detecting a change in an operating mode includes detecting a change in an operating environment of said IC.

28. A system for determining the performance characteristics of an Integrated-Circuit (IC) comprising circuitry operating in accordance with a particular application, said system comprising:
means for detecting an operating mode of said IC;
BIST test circuit means for testing said IC, wherein said test circuit means is operatively coupled to said voltage island under test for testing said circuitry to determine the lowest operating voltage required by the IC circuitry to provide for a passing BIST test, said BIST means further generating a control signal representing said lowest operating voltage for that operating mode; and,
means associated with said IC circuitry for storing said control signal.

29. The system as claimed in claim 28, further comprising means for adjusting a power supply voltage applied to the IC circuitry based on the stored control signal so as to provide a minimum operating voltage for said IC circuitry according to a particular operating mode.

30. The system as claimed in claim 29, wherein said minimum operating voltage value comprises a lowest working voltage value in addition to a predetermined voltage amount comprising a safety margin voltage.

31. The system as claimed in claim 29, wherein said operating mode of said IC comprises one of: application speed operational setting, or standby mode of operation, said test circuit means respectively testing said IC at said application speed when testing application speed mode of operation or, a very slow speed operation when testing in standby mode operation.

32. The system as claimed in claim 28, wherein said storing means comprises one or more programmable fuse devices or latch devices adapted for storing said control signal.
